(19) United States
(12) Patent Application Publication
(10) Pub. No.: US 2024/0136240 A1
(43) Pub. Date: Apr. 25, 2024

(54) SEMICONDUCTOR DEVICES WITH EMBEDDED FILLER PARTICLES AND ASSOCIATED METHODS FOR THEIR PRODUCTION

(71) Applicant: Infineon Technologies AG, Neubiberg (DE)

(72) Inventors: Martin MAYER, Nittendorf (DE); Rainer Markus SCHALLER, Aichen (DE)

(21) Appl. No.: 18/485,953

(22) Filed: Oct. 11, 2023

(30) Foreign Application Priority Data
Oct. 19, 2022 (DE) 102022127718.6

(51) Int. Cl. H01L 23/29; H01L 21/56; H01L 23/00; H01L 23/31

(52) U.S. Cl. CPC H01L 23/295; H01L 21/565; H01L 23/3107; H01L 24/48; H01L 2224/48245; H01L 2924/186

(57) ABSTRACT

A semiconductor device contains a chip carrier and a semiconductor chip arranged on the chip carrier. Furthermore, the semiconductor device comprises an intermediate layer arranged between the chip carrier and the semiconductor chip, and an encapsulation material at least partially encapsulating the semiconductor chip. Filler particles are embedded in at least one of the interlayer or the encapsulation material, wherein the filler particles contain a semiconductor material with a band gap in a range from 2.3 eV to 3.6 eV.

### TECHNICAL FIELD

The present disclosure relates to semiconductor devices with embedded filler particles, and associated methods for their production.

### BACKGROUND

In semiconductor devices, high electrical voltage differences between individual device components may occur during operation. For example, increased electrical potential differences may arise in a current sensor between a busbar and a sensor chip arranged above it. Depending on material properties and the relative arrangement of the device components, increased voltage differences can lead to enormously high electric field strengths in certain spatial regions of the device. Device components arranged there can be subject to wear due to the high electrical field strengths, which in the worst case can lead to failure of the device. Manufacturers and developers of semiconductor devices are constantly striving to improve their products. As part of this effort there may be a particular focus both on extending the service life of the devices and ensuring their continuous safe operation.

### SUMMARY

Various aspects relate to a semiconductor device. The semiconductor device comprises a chip carrier and a semiconductor chip arranged on the chip carrier. The semiconductor device further comprises an intermediate layer arranged between the chip carrier and the semiconductor chip, and an encapsulation material at least partially encapsulating the semiconductor chip. The semiconductor device further comprises filler particles embedded in at least one of the intermediate layer or the encapsulation material. The filler particles comprise a semiconductor material with a band gap in a range from 2.3 eV to 3.6 eV.

Various aspects relate to a semiconductor device. The semiconductor device comprises a chip carrier and a semiconductor chip arranged on the chip carrier. The semiconductor device further comprises an intermediate layer arranged between the chip carrier and the semiconductor chip, and an encapsulation material at least partially encapsulating the semiconductor chip. The semiconductor device further comprises filler particles embedded in at least one of the intermediate layer or the encapsulation material. The filler particles are configured to increase at least one of an electrical conductivity of the intermediate layer or an electrical conductivity of the encapsulation material into a range from 10⁻¹⁶ S/m to 10⁻² S/m upon an increase in an electric field strength to a value of more than 5 V/μm.

Various aspects relate to a method for producing a semiconductor device. The method comprises arranging an intermediate layer on a chip carrier and arranging a semiconductor chip on the intermediate layer. The method also comprises encapsulating the semiconductor chip with an encapsulation material. Filler particles are embedded in at least one of the intermediate layer or the encapsulation material. The filler particles comprise a semiconductor material with a band gap in a range from 2.3 eV to 3.6 eV.

Various aspects relate to a method for producing a semiconductor device. The method comprises arranging an intermediate layer on a chip carrier and arranging a semiconductor chip on the intermediate layer. The method also comprises encapsulating the semiconductor chips with an encapsulation material. Filler particles are embedded in at least one of the intermediate layer or the encapsulation material. The filler particles are configured to increase at least one of an electrical conductivity of the intermediate layer or an electrical conductivity of the encapsulation material to a range from 10⁻¹⁶ S/m to 10⁻² S/m upon an increase in an electric field strength to a value of more than 5 V/μm.

### BRIEF DESCRIPTION OF THE DRAWINGS

Devices and methods according to the disclosure are described in more detail in the following with the aid of drawings. The elements shown in the drawings are not necessarily reproduced true to scale relative to each other. Identical reference signs can refer to identical components.

FIG. 1 shows, schematically, a perspective view of a semiconductor device 100.

FIG. 2 shows, schematically, a cross-sectional side view of a semiconductor device 200, and field lines of an electric field occurring in the semiconductor device 200.

FIG. 3 shows, schematically, a cross-sectional side view of a semiconductor device 300 according to the disclosure.

FIG. 4 shows, schematically, a cross-sectional side view of a semiconductor device 400 according to the disclosure.

FIG. 5 shows, schematically, a cross-sectional side view of a semiconductor device 500 according to the disclosure.

FIG. 6 shows a flowchart of a method for producing a semiconductor device according to the disclosure.

FIG. 7 shows a flowchart of a method for producing a semiconductor device according to the disclosure.

FIG. 8 illustrates electrical conductivities of a material with embedded silicon carbide filler particles as a function of an electric field. The electrical conductivities of the material are shown for different percentages by weight of the filler particles.

FIG. 9 illustrates electrical current densities in a material with embedded zinc oxide filler particles as a function of an electric field. The electrical current densities are shown for different percentages by weight of filler particles.

FIG. 10 illustrates electrical current densities in different materials with embedded zinc oxide filler particles as a function of an electric field. The electrical current densities are shown for different sizes and shapes of filler particles.

### DETAILED DESCRIPTION

The following description makes reference to the accompanying drawings. The drawings illustrate concrete implementations in which the present disclosure can be implemented in practice by way of example. The following detailed description is therefore not to be interpreted in a restrictive sense.

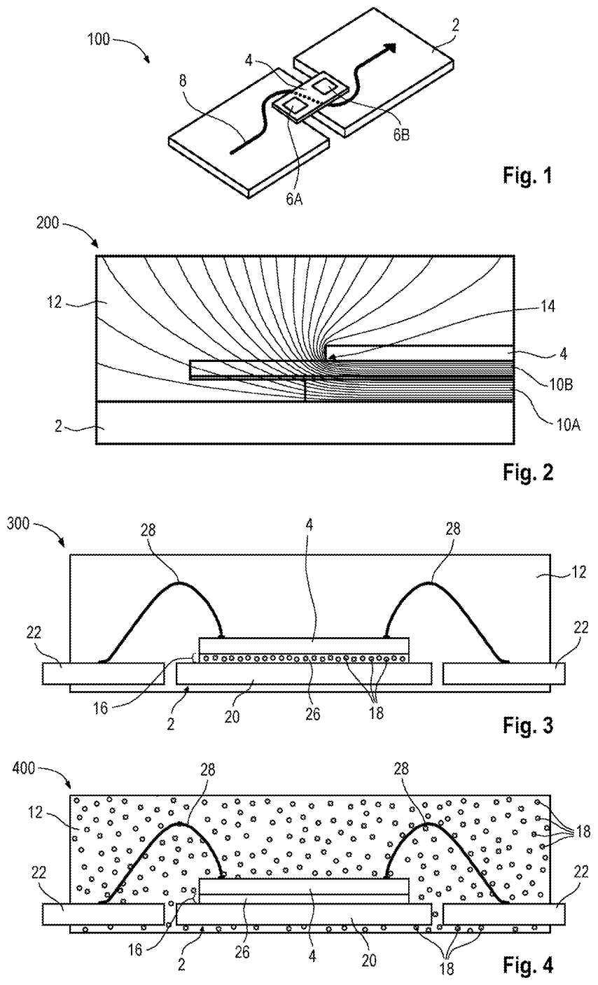

FIGS. 1 and 2 and their description are intended to illustrate, in a qualitative and example manner, a technical problem addressed by the present disclosure. However, the present disclosure is not restricted to the types of devices shown in FIGS. 1 and 2.

The semiconductor device 100 of FIG. 1 may comprise a chip carrier 2 and a semiconductor chip 4 arranged above it. The semiconductor chip 4 can be, for example, a magnetic field sensor chip with at least one sensor element. In the specific example of FIG. 1, the semiconductor chip 4 can correspond to a differential magnetic field sensor chip having two Hall sensor elements 6A, 6B.

The electrically conductive chip carrier 2 can fulfil the function of a busbar and be configured to conduct an electrical measurement current 8. In the example shown, the chip carrier 2, or the busbar formed thereby, can have two indentations so that the measurement current 8 can take an S-shaped course around the two sensor elements 6A, 6B. A magnetic field can be induced at the locations of the sensor elements 6A, 6B by the measurement current 8. The semiconductor chip 4 can be configured to detect the induced magnetic field at the positions of the sensor elements 6A, 6B. Based on the detected magnetic field (or based on an associated differential measurement signal), the strength of the measurement current 8 can be determined. For this reason, the semiconductor chip 4 or the semiconductor device 100 can also be referred to as a current sensor.

The semiconductor device 200 of FIG. 2 can have one or more features of the semiconductor device 100 of FIG. 1. The semiconductor device 200 may contain a chip carrier 2 and a semiconductor chip 4 arranged above the chip carrier 2. A stack of different layers 10 can be arranged between the chip carrier 2 and the semiconductor chip 4. In the example shown, the layer stack can have two dielectric layers 10A, 10B. The device components can be at least partially encapsulated by an encapsulation material 12.

During operation of the semiconductor device 200, large electrical potential differences may occur between the chip carrier 2 and the semiconductor chip 4. For example, these voltage differences can assume values of more than 1,000 Volts. Galvanic separation or galvanic isolation between the chip carrier 2 and the semiconductor chip 4 can be provided by the interposed dielectric layers 10A, 10B. Since the dielectric layers 10A, 10B have an electrical insulation capability, high electric field strengths can build up in certain spatial regions of the semiconductor device 200. In FIG. 2, an electric field occurring within the semiconductor device 200 is illustrated by electric field lines.

In the case shown, by way of example a compression of the electric field lines may occur in a (spatial) region 14 in which the semiconductor chip 4, the encapsulation material 12 and the upper dielectric layer 10B are adjacent to one another. In other words, comparatively high electric field strengths can occur in the region 14. Materials arranged in the region 14 can be subjected to high levels of stress due to the high electric field strengths, which can be problematic in particular for materials with limited insulation capacity. For example, an adhesive layer arranged between the top of the upper dielectric layer 10B and the underside of the semiconductor chip 4 based on epoxy, silicone or acrylate, may not necessarily be configured for high electrical insulation. The stress mentioned can then lead to accelerated aging of the materials, which can lead to undesirable electrical discharges within the device and, in the worst case, to failure of the device.

In the following, example semiconductor devices according to the disclosure and methods for producing such semiconductor devices are described. The semiconductor devices can provide reduced internal electric field strengths and thus contribute at least partly to a solution of the technical problem.

The semiconductor device 300 of FIG. 3 may have one or more features of semiconductor devices described earlier. The semiconductor device 300 may contain a chip carrier 2 and a semiconductor chip 4 arranged above the chip carrier 2. An intermediate layer 16 can be arranged between the chip carrier 2 and the semiconductor chip 4. In the example shown, the intermediate layer 16 may comprise one or more dielectric layers 26. Filler particles 18 can be embedded in the intermediate layer 16. The device components can be at least partially encapsulated by an encapsulation material 12.

The filler particles 18 may contain a semiconductor material with a band gap in a range from approximately 2.3 eV to approximately 3.6 eV or be made of such a material. In this context, the filler particles 18 may contain, for example, at least one of zinc oxide or silicon carbide.

The electrical conductivity of the intermediate layer 16 can depend on a content of the filler particles 18 in the intermediate layer 16 and can be adjusted thereby. In general, the proportion of filler particles 18 in the intermediate layer 16 may have a value in a range from approximately 1 percent by weight (wt. %) to approximately 99 percent by weight. In general, the proportion of filler particles 18 in the intermediate layer 16 may have a value in a range from approximately 15 percent by weight to approximately 60 percent by weight. In further examples, the proportion of filler particles 18 in the intermediate layer 16 can also be chosen differently. In this case, the proportion can lie in a value range with a lower limit and an upper limit, wherein the lower limit can assume a value of, for example, 5, 10, 15, 20, 25 or 30 percent by weight and the upper limit a value of, for example, 50, 60, 70, 80 or 90 percent by weight.

The electrical conductivity of the intermediate layer 16 can additionally depend on maximum dimensions of the filler particles 18 and can be adjusted thereby. For example, in the case of substantially spherical filler particles 18, a maximum dimension can correspond to a maximum diameter of the filler particles 18. In general, the filler particles 18 can have maximum dimensions in a range from approximately 1 μm to approximately 300 μm. In some implementations, the filler particles can have maximum dimensions in a range from approximately 30 μm to approximately 100 μm. In further examples, the maximum dimensions of the filler particles 18 can also be selected differently. In this case, the maximum dimensions can lie in a value range with a lower limit and an upper limit, wherein the lower limit can assume a value of, for example, 10, 20, 30, 40 or 50 μm and the upper limit a value of, for example, 75, 100, 150, 200 or 250 μm.

The filler particles 18 can in general have any desired geometric shape. In some implementations, the filler particles 18 may be substantially spherical. In other implementations, the filler particles 18 may be irregularly shaped.

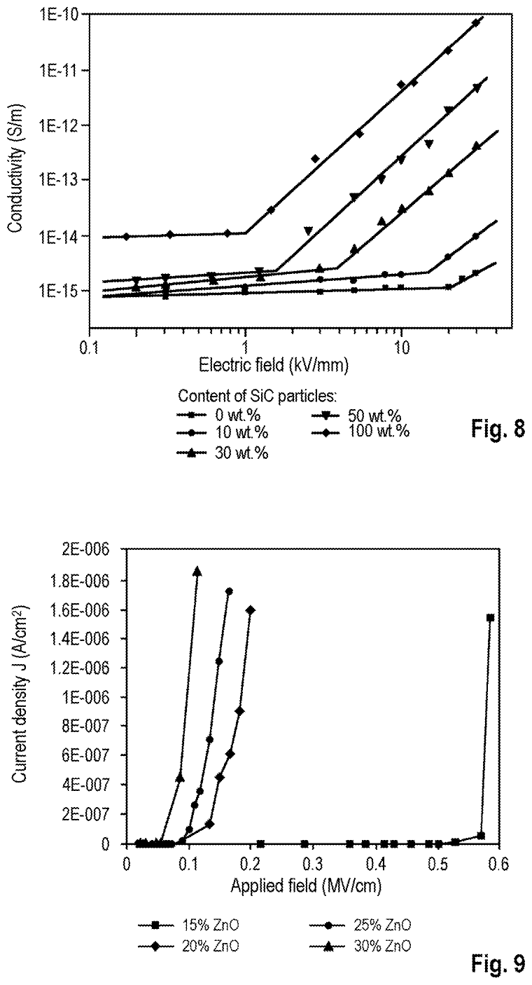

The filler particles 18 can be configured to increase an electrical conductivity of the intermediate layer 16 into a range from approximately 10⁻¹⁶ S/m to 10⁻² S/m upon an increase in an electric field strength to a value of more than 5 V/μm. Preferably, the filler particles 18 can be configured to increase the electrical conductivity of the intermediate layer 16 into a range from approximately 10⁻¹² S/m to 10⁻⁶ S/m upon such an increase in the electric field strength. In some implementations, the values mentioned can be selected differently. The above example value of the electric field strength of more than approximately 5 V/μm can be replaced in other examples by a value of more than, for example, 6, 7, 8, 9 or 10 V/μm. Furthermore, the electrical conductivity of the intermediate layer 16 can be increased to a range with a lower limit and an upper limit, wherein the lower limit can assume a value from approximately 10⁻¹⁶, 10⁻¹⁵, 10⁻¹⁴, 10⁻¹³, 10⁻¹², 10⁻¹¹, 10⁻¹⁰ or 10⁻⁹ S/m and the upper limit can assume a value of approximately 10⁻⁷, 10⁻⁶, 10⁻⁵, 10⁻⁴, 10⁻³ or 10⁻² S/m. FIGS. 8 to 10 show example electrical conductivities of materials with embedded filler particles as a function of electric field strengths. However, it should be noted that the present disclosure is not limited to the values stated there.

In the example shown, the filler particles 18 may be embedded in the dielectric layer 26 or in a stack of a plurality of dielectric layers. The dielectric layer 26 may be configured to provide galvanic isolation between the chip carrier 2 and the semiconductor chip 4. In one example, the dielectric layer 26 may contain or be produced from an inorganic material. The inorganic material can comprise, for example, at least one of a glass material or a ceramic material. Alternatively or in addition, the dielectric layer 26 can contain or be produced from an organic material. The organic material can comprise, for example, at least one of a polymer, a polyimide, an epoxy or a silicone.

The chip carrier 2 is not restricted to a specific type of carrier. In particular, the chip carrier 2 can be made at least partially of an electrically conductive material, so that galvanic isolation between the chip carrier 2 and the semiconductor chip 4 may be necessary. In the example shown, the chip carrier 2 can be a lead frame, which can be manufactured at least partly from a metal and/or a metal alloy. The lead frame may comprise one or more diepads 20 and one or more connecting conductors (leads) 22. In the side view of FIG. 3, further leads may be arranged behind the illustrated leads 22 and concealed by them. The semiconductor chip 4 can be mounted on the top of the diepad 20. The lead frame or the diepad 20 may be configured as a busbar, as already described in connection with FIG. 1.

The encapsulation material 12 may contain or be made of an electrically insulating material. One or more components of the semiconductor device 300 can be encapsulated by the encapsulation material 12 and thus protected against external influences, such as moisture or mechanical shocks. The encapsulation material 12 can form a housing, so that the semiconductor device 300 can also be referred to as a semiconductor housing or semiconductor package. The encapsulation material 12 can contain at least one of a molding compound, an epoxy, an imide, a thermoplastic, a thermoset polymer, a polymer mixture, a glob-top material, a laminate, etc. For producing the housing formed by the encapsulation material 12, various techniques can be used, for example, at least one of compression molding, injection molding, powder molding, liquid molding, map molding, laminating, etc.

In addition to the components already mentioned, the semiconductor device 300 may optionally comprise one or more electrical connecting elements (e.g., bond wires) 28, which can electrically connect the semiconductor chip 4 to the leads 22. The leads 22 can remain at least partially uncovered by the encapsulation material 12, so that the semiconductor chip 4 can be electrically contacted from outside the housing.

As already described in connection with FIG. 2, electrical voltage differences between the chip carrier 2 and the semiconductor chip 4 arising during operation of the semiconductor device 300 can give rise to locally increased electric field strengths within the semiconductor device 300. The filler particles 18 can be configured to at least partially reduce these increased electric field strengths. On account of the increased electrical conductivity of the intermediate layer 16 caused by the filler particles 18, a locally bounded displacement of charge carriers can occur in the intermediate layer 16 or at the positions of the filler particles 18. Due to this charge carrier displacement, the voltage differences and thereby elevated electric field strengths can be at least partially reduced in the associated spatial regions. The displacement of the charge carriers can create a new equilibrium in which previously compressed electric field lines are spread further apart.

In this context, it should be noted that the charge carrier displacement described above does not have to or cannot affect fundamental insulation properties of the intermediate layer 16. This means that, despite the charge carrier displacement, the intermediate layer 16 or the dielectric layer 26 can still act as a dielectric and provide sufficient galvanic isolation between the chip carrier 2 and the semiconductor chip 4. Although the electrical conductivity of the intermediate layer 16 may be increased by the filler particles 18 at sufficiently high electric field strengths, it may still be several orders of magnitude lower than the electrical conductivity of an electrical conductor, which can typically be greater than 10⁶ S/m. Due to the charge carrier displacement, therefore, for example, an insulation path provided by the intermediate layer 16 between the chip carrier 2 and the semiconductor chip 4 cannot be bridged. Furthermore, the charge carrier displacement cannot lead to undesirable electrical currents occurring within the semiconductor device 300.

As previously described, the use of the filler particles 18 can reduce the electric field strength, in particular at positions of the filler particles 18. The filler particles 18 can thus preferably be arranged in a spatial region in which an electric field strength is increased due to a geometric shape of at least one of the semiconductor chip 4, the intermediate layer 16, the chip carrier 2 or the encapsulation material 12. In one example, the filler particles 18 can be arranged at least at one of an edge or a tip of the semiconductor chip 4. There, the electric field lines can be compressed and high electric field strengths can develop. In a specific example, the filler particles 18 can be arranged in a region in which the semiconductor chip 4, the encapsulation material 12 and the intermediate layer 16 are adjacent to one another. Such a region is described in connection with FIG. 2.

In one example, the filler particles 18 can be arranged solely at such positions within the intermediate layer 16 where increased electric field strengths may occur. In some implementations, however, the filler particles 18 can be distributed homogeneously and completely over the entire intermediate layer 16. In comparison to a locally bounded arrangement of the filler particles 18 within the intermediate layer 16, a homogeneous distribution of the filler particles 18 over the entire intermediate layer 16 can be more cost-effective and simpler to implement.

The semiconductor devices according to the disclosure described herein can provide the technical effects described below in addition to the reduction of the electric field strength already described. Purely by way of example, reference may be made in the following to the semiconductor device 300 of FIG. 3. However, it is clear that the aforementioned technical effects can also be provided by any other semiconductor device described herein.

By using the filler particles 18 and the resulting reduction of electric field strengths within the semiconductor device 300, wear of the device components can be prevented. This can prevent premature aging of the components and increase the service life of the components. The risk of failure of the semiconductor device 300 can thus be reduced. In addition, the extended service life can save energy and material resources.

Reducing the electric field strengths allows electrical discharges, electrical partial discharges and/or air penetration within the semiconductor device 300 to be prevented. Due to aging processes, air cavities or air bubbles may be formed in the device, for example at an interface between the encapsulation material 12 and the intermediate layer 16. Due to the reduced electric field strengths, the risk of discharges along air passages in the air cavities can be reduced.

By reducing the electric field strengths, additional components for improved galvanic isolation within the semiconductor device or in a higher-level system can be dispensed with. The necessary galvanic isolation in the semiconductor devices according to the disclosure can be provided completely and in particular by the use of the filler particles 18. The devices described herein therefore represent simplified and cost-effective solutions.

Due to the reduction of electric field strengths achieved, insulation standards specified by industry norms can be satisfied. The industry norms available at the time of this disclosure can be the IEC 60664 and IEC 60747-17 standards. However, it should be noted in this context that the present disclosure is in no way limited to the cited standards or device types related to these. The concepts described herein can naturally also be used in other technical areas or devices.

The semiconductor devices described herein can be used, for example, in highly efficient resource-conserving electric power drives. Electric drives can contribute at least in part to reducing global carbon dioxide emissions. The semiconductor devices described herein can thus contribute at least indirectly to green technology solutions, e.g., to climate-friendly solutions that provide a reduced energy and material consumption.

The semiconductor device 400 of FIG. 4 may have one or more features of previously described semiconductor devices. In contrast to FIG. 3, the filler particles 18 in the semiconductor device 400 can be embedded in the encapsulation material 12. In the example shown, the filler particles 18 can be distributed homogeneously and completely over the entire encapsulation material 12. By analogy to FIG. 3, the filler particles 18 in FIG. 4 may be configured to increase an electrical conductivity of the encapsulation material 12 into a certain range upon an increase in an electric field strength to a certain value. All relevant statements in connection with FIG. 3 can also be transferred to the example of FIG. 4. In particular, all statements relating to the filler particles 18, their properties, their technical effects, etc., can apply analogously to the semiconductor device 400 of FIG. 4. For the sake of simplicity, reference is made to the description of FIG. 3 in this regard.

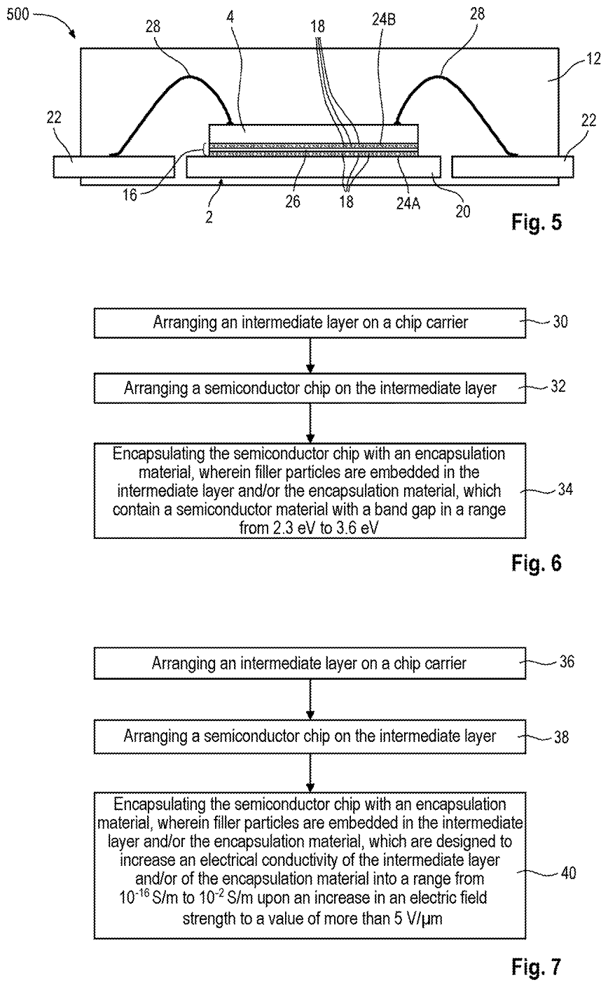

The semiconductor device 500 of FIG. 5 may have one or more features of previously described semiconductor devices. In the semiconductor device 500, the intermediate layer 16 may contain one or more adhesive layers (or bonding layers) 24, which may be configured, inter alia, to fix the semiconductor chip 4 to the chip carrier 2. In the case shown, the intermediate layer can comprise, for example, two adhesive layers 24A, 24B. The lower adhesive layer 24A can fix the underside of a dielectric layer 26 to the top of the chip carrier 2, while the upper adhesive layer 24B can fix a top of the dielectric layer 26 to the underside of the semiconductor chip 4. The adhesive layers 24A, 24B may contain an electrically insulating material or be made of such a material.

In contrast to the examples of FIGS. 3 and 4, the filler particles 18 in the semiconductor device 500 can be embedded in at least one of the adhesive layers 24A, 24B. In the example shown, the filler particles 18 can be distributed homogeneously and completely over the total volumes of the adhesive layers 24A, 24B. By analogy to the examples of FIGS. 3 and 4, the filler particles 18 in FIG. 5 may be configured to increase an electrical conductivity of the encapsulation material 12 into a certain range upon an increase in an electric field strength to a certain value. All relevant statements in connection with FIGS. 3 and 4 can naturally also apply to the filler particles 18 of FIG. 5.

In the previously described examples of FIGS. 3 to 5, the filler particles 18 were in each case embedded in a single component of the respective semiconductor device. For example, the filler particles 18 in the example of FIG. 4 were contained only in the encapsulation material 12. In this context, however, it should be noted that features of FIGS. 3 to 5 can be arbitrarily combined in further examples. In general, the filler particles 18 can thus be contained in at least one of the intermediate layer 16, the dielectric layer 26, the adhesive layer 24 or the encapsulation material 12. For the sake of simplicity, not all possible combinations of features are explicitly presented and described here. However, it will be clear to the person skilled in the art that a reduction of increased electric field strengths can also be achieved by use of the filler particles 18 in more than one single component.

Furthermore, it should be noted that the filler particles 18 described herein can be used in different types of device and their use is not limited to a particular type of device. In one example, the filler particles 18 can be used in a current sensor, an example of which is described in FIG. 1. This means that a semiconductor device according to the disclosure can be part of a current sensor. In another example, the filler particles 18 may be used in a semiconductor device according to the disclosure, which may be part of a gate driver or a discrete component. In some implementations, it may be practical to use filler particles 18 in such devices which are configured to provide certain insulation functions, such as, for example, the already described galvanic isolation between a busbar and a semiconductor chip arranged above it.

FIGS. 6 and 7 show flow diagrams for methods for producing semiconductor devices according to the disclosure. The illustrated methods can be used, for example, to produce one of the semiconductor devices described above and can thus be read in conjunction with the preceding figures. The methods are presented in a general manner, in order to describe aspects of the disclosure in qualitative terms. Each of the methods may have further aspects. For example, a method can be extended by one or more of the aspects that are described in conjunction with other examples described herein.

In the method of FIG. 6, at step 30 an intermediate layer can be arranged on a chip carrier. At step 32, a semiconductor chip can be arranged on the intermediate layer. At step 34, the semiconductor chip can be encapsulated with an encapsulation material. Filler particles can be embedded in at least one of the interlayer or the encapsulation material, the filler particles containing a semiconductor material with a band gap in a range from approximately 2.3 eV to approximately 3.6 eV.

In the method of FIG. 7, at step 36 an intermediate layer can be arranged on a chip carrier. At step 38, a semiconductor chip can be arranged on the intermediate layer. At step 40, the semiconductor chip can be encapsulated with an encapsulation material. Filler particles can be embedded in at least one of the intermediate layer or the encapsulation material. The filler particles can be configured to increase at least one of an electrical conductivity of the intermediate layer or an electrical conductivity of the encapsulation material into a range from approximately 10⁻¹⁶ S/m to approximately 10⁻² S/m upon an increase in an electric field strength to a value of more than 5 V/μm.

FIG. 8 relates to electrical properties of a material with silicon carbide filler particles embedded therein. In the example illustration of FIG. 8, the conductivity of the material (in S/m) is plotted against the strength of a prevailing electric field (in kV/mm) for different amounts of the filler particles (in wt. %). FIG. 8 shows five curves for filler particle contents of 0, 10, 30, 50 and 100 percent by weight respectively.

It can be seen from FIG. 8 that the electrical conductivity of the material increases more rapidly above a specific value of the electric field strength. For example, the electrical conductivity of the material with a filler particle content of approximately 30 percent by weight increases more rapidly above a value of the electric field of approximately 4 kV/mm. The higher the content of filler particles, the lower the value of the electric field strength at which the electrical conductivity of the material increases more rapidly.

FIG. 9 relates to the electrical properties of a material with embedded zinc oxide filler particles. In the example illustration of FIG. 9, the current density J (in A/cm²) of a current J flowing through the material is plotted against the strength of a prevailing electric field (in MV/cm) for different values of the content of filler particles (in wt. %). An increased current density J can be based on an increased electrical conductivity of the material. FIG. 9 shows four curves for filler particle contents of 15, 20, 25 and 30 percent, respectively. Analogously to FIG. 8, it is apparent from the curves of FIG. 9 that an increased filler particle content provides an increase in the material conductivity at lower electric field strengths.

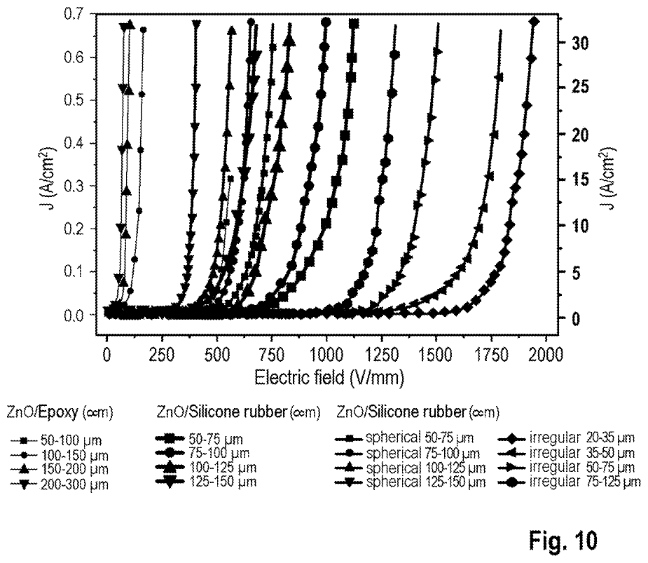

FIG. 10 relates to electrical properties of different materials with embedded zinc oxide filler particles. In the example illustration of FIG. 10, for different dimensions (in μm) and different geometric shapes (cf. “spherical” and “irregular”) of the filler particles, a current density J of a current flowing through the material (in mA/cm² or ∝ A/cm²) is plotted against the strength of a prevailing electric field E (in V/mm). From FIG. 10, it is apparent, inter alia, that filler particles with larger dimensions provide an increase in the current density at lower electric field strengths.

FIG. 10 shows three groups of curves. The first group concerns an epoxy filled with zinc oxide filler particles and includes four thin curves that relate to (in particular maximum) dimensions of filler particles in the ranges from 50 μm to 100 μm, from 100 μm to 150 μm, from 150 μm to 200 μm and from 200 μm to 300 μm. The current density is indicated on the left-hand side of the diagram in units of mA/cm².

The second group concerns a silicone rubber filled with zinc oxide filler particles and includes four curves that relate to filler particles with (in particular maximum) dimensions in ranges from 50 μm to 75 μm, from 75 μm to 100 μm, from 100 μm to 125 μm and from 125 μm to 150 μm. In this case the current density J is indicated on the right-hand side of the diagram in units ∝ A/cm².

The third group concerns a silicone rubber filled with zinc oxide filler particles and contains eight thick curves. Four curves relate to spherical filler particles with (in particular maximum) dimensions in the range from 50 μm to 75 μm, from 75 μm to 100 μm, from 100 μm to 125 μm and from 125 μm to 150 μm. Four further curves relate to irregularly shaped filler particles with (in particular maximum) dimensions in the range from 20 μm to 35 μm, from 35 μm to 50 μm, from 50 μm to 75 μm and from 75 μm to 125 μm. In this case the current density J is indicated on the right-hand side of the diagram in units ∝ of A/cm².

### ASPECTS

In the following, semiconductor devices and associated production methods are explained based on examples.

Aspect 1 is a semiconductor device comprising: a chip carrier; a semiconductor chip arranged on the chip carrier; an intermediate layer arranged between the chip carrier and the semiconductor chip; an encapsulation material at least partially encapsulating the semiconductor chip; and filler particles embedded in at least one of the intermediate layer or the encapsulation material, wherein the filler particles comprise a semiconductor material with a band gap in a range from 2.3 eV to 3.6 eV.

Aspect 2 is a semiconductor device according to aspect 1, wherein the filler particles comprises at least one of zinc oxide or silicon carbide.

Aspect 3 is a semiconductor device according to aspect 1 or 2, wherein the filler particles are configured to increase at least one of an electrical conductivity of the intermediate layer or an electrical conductivity of the encapsulation material into a range from 10⁻¹⁶ S/m to 10⁻² S/m upon an increase in an electric field strength to a value of more than 5 V/μm.

Aspect 4 is a semiconductor device according to aspect 3, wherein the increase in the electrical conductivity is configured to reduce the electric field strength at positions of the filler particles.

Aspect 5 is a semiconductor device according to any of the preceding aspects, wherein a proportion of the filler particles in at least one of the intermediate layer or the encapsulation material has a value in a range from 1 percent by weight to 99 percent by weight.

Aspect 6 is a semiconductor device according to any of the preceding aspects, wherein the filler particles have maximum dimensions in a range from 1 μm to 300 μm.

Aspect 7 is a semiconductor device according to any of the preceding aspects, wherein the filler particles are arranged in a region in which an electric field strength is increased due to a geometric shape of at least one of the semiconductor chip, the intermediate layer, the chip carrier or the encapsulation material.

Aspect 8 is a semiconductor device according to any of the preceding aspects, wherein the filler particles are arranged at least at one of an edge or a tip of the semiconductor chip.

Aspect 9 is a semiconductor device according to any of the preceding aspects, wherein the filler particles are arranged in a region in which the semiconductor chip, the encapsulation material and the intermediate layer are adjacent to one another.

Aspect 10 is a semiconductor device according to any of the preceding aspects, wherein the filler particles are distributed homogeneously and completely over the entire encapsulation material.

Aspect 11 is a semiconductor device according to any of the preceding aspects, wherein the filler particles are distributed homogeneously and completely over the entire intermediate layer.

Aspect 12 is a semiconductor device according to any of the preceding aspects, wherein: the intermediate layer comprises a dielectric layer, which is configured to provide galvanic isolation between the chip carrier and the semiconductor chip, and the filler particles are embedded in the dielectric layer.

Aspect 13 is a semiconductor device according to any of the preceding aspects, wherein: the intermediate layer comprises an adhesive layer, which is configured to fix the semiconductor chip to the chip carrier, and the filler particles are embedded in the adhesive layer.

Aspect 14 is a semiconductor device according to any of the preceding aspects, wherein the encapsulation material comprises at least one of a molding compound, an epoxy, an imide, a thermoplastic, a thermoset polymer, a polymer mixture, a glob-top material or a laminate.

Aspect 15 is a semiconductor device according to any of the preceding aspects, wherein: the chip carrier comprises a current conductor which is configured to carry a measurement current, and the semiconductor chip is part of a current sensor which is configured to detect a strength of the measurement current.

Aspect 16 is a semiconductor device according to any of the preceding aspects, wherein the semiconductor chip is part of a gate driver.

Aspect 17 is a semiconductor device comprising: a chip carrier; a semiconductor chip arranged on the chip carrier; an intermediate layer arranged between the chip carrier and the semiconductor chip; an encapsulation material at least partially encapsulating the semiconductor chip; and filler particles embedded in at least one of the intermediate layer or the encapsulation material, which are configured to increase at least one of an electrical conductivity of the intermediate layer or an electrical conductivity of the encapsulation material into a range from 10⁻¹⁶ S/m to 10⁻² S/m upon an increase in an electric field strength to a value of more than 5 V/μm.

Aspect 18 is a semiconductor device according to aspect 17, wherein the filler particles comprise a semiconductor material with a band gap in a range from 2.3 eV to 3.6 eV.

Aspect 19 is a method for producing a semiconductor device, the method comprising: arranging an intermediate layer on a chip carrier; arranging a semiconductor chip on the intermediate layer; and encapsulating the semiconductor chip with an encapsulation material, wherein filler particles comprising a semiconductor material with a band gap in a range from 2.3 eV to 3.6 eV are embedded in at least one of the intermediate layer or the encapsulation material.

Aspect 20 is a method for producing a semiconductor device, the method comprising: arranging an intermediate layer on a chip carrier; arranging a semiconductor chip on the intermediate layer; and encapsulating the semiconductor chip with an encapsulation material, wherein filler particles are embedded in at least one of the intermediate layer or the encapsulation material, which are configured to increase at least one of an electrical conductivity of the intermediate layer or an electrical conductivity of the encapsulation material into a range from 10⁻¹⁶ S/m to 10⁻² S/m upon an increase in an electric field strength to a value of more than 5 V/μm.

Although specific implementations have been illustrated and described herein, it is obvious to the person skilled in the art that a plurality of alternative and/or equivalent implementations can replace the specific implementations shown and described, without departing from the scope of the present disclosure. This application is intended to include all modifications or variations of the specific implementations discussed herein. It is therefore intended that this disclosure is limited only by the claims and their equivalents.

1. A semiconductor device, comprising:
a chip carrier;
a semiconductor chip arranged on the chip carrier;
an intermediate layer arranged between the chip carrier and the semiconductor chip;
an encapsulation material at least partially encapsulating the semiconductor chip; and
filler particles embedded in at least one of the intermediate layer or the encapsulation material,
wherein the filler particles comprise a semiconductor material with a band gap in a range from 2.3 eV to 3.6 eV.

2. A semiconductor device as claimed in claim 1, wherein the filler particles comprise at least one of zinc oxide or silicon carbide.

3. The semiconductor device as claimed in claim 1, wherein the filler particles are configured to increase at least one of an electrical conductivity of the intermediate layer or an electrical conductivity of the encapsulation material into a range from 10⁻¹⁶ S/m to 10⁻² S/m upon an increase in an electric field strength to a value of more than 5 V/μm.

4. The semiconductor device as claimed in claim 3, wherein the increase in the electrical conductivity is configured to reduce the electric field strength at positions of the filler particles.

5. The semiconductor device as claimed in claim 1, wherein a proportion of the filler particles in at least one of the intermediate layer or the encapsulation material has a value in a range from 1 percent by weight to 99 percent by weight.

6. The semiconductor device as claimed in claim 1, wherein the filler particles have maximum dimensions in a range from 1 μm to 300 μm.

7. The semiconductor device as claimed in claim 1, wherein the filler particles are arranged in a region in which an electric field strength is increased due to a geometric shape of at least one of the semiconductor chip, the intermediate layer, the chip carrier, or the encapsulation material.

8. The semiconductor device as claimed in claim 1, wherein the filler particles are arranged at least at one of an edge of the semiconductor chip or a tip of the semiconductor chip.

9. The semiconductor device as claimed in claim 1, wherein the filler particles are arranged in a region in which the semiconductor chip, the encapsulation material, and the intermediate layer are adjacent to one another.

10. The semiconductor device as claimed in claim 1, wherein the filler particles are distributed homogeneously and completely over an entire portion of encapsulation material.

11. The semiconductor device as claimed in claim 1, wherein the filler particles are distributed homogeneously and completely over an entire portion of intermediate layer.

12. The semiconductor device as claimed in claim 1, wherein:
the intermediate layer comprises a dielectric layer, which is configured to provide galvanic isolation between the chip carrier and the semiconductor chip, and
the filler particles are embedded in the dielectric layer.

13. The semiconductor device as claimed in claim 1, wherein:
the intermediate layer comprises an adhesive layer, which is configured to fix the semiconductor chip to the chip carrier, and
the filler particles are embedded in the adhesive layer.

14. The semiconductor device as claimed in claim 1, wherein the encapsulation material comprises at least one of a molding compound, an epoxy, an imide, a thermoplastic, a thermoset polymer, a polymer mixture, a glob-top material or a laminate.

15. The semiconductor device as claimed in claim 1, wherein:
the chip carrier comprises a current conductor that is configured to carry a measurement current, and
the semiconductor chip is part of a current sensor that is configured to detect a strength of the measurement current.

16. The semiconductor device as claimed in claim 1, wherein the semiconductor chip is part of a gate driver.

17. A semiconductor device, comprising:
a chip carrier;
a semiconductor chip arranged on the chip carrier;
an intermediate layer arranged between the chip carrier and the semiconductor chip;
an encapsulation material at least partially encapsulating the semiconductor chip; and
filler particles embedded in at least one of the intermediate layer or the encapsulation material, which are configured to increase at least one of an electrical conductivity of the intermediate layer or an electrical conductivity of the encapsulation material into a range from 10⁻¹⁶ S/m to 10⁻² S/m upon an increase in an electric field strength to a value of more than 5 V/μm.

18. The semiconductor device as claimed in claim 17, wherein the filler particles comprise a semiconductor material with a band gap in a range from 2.3 eV to 3.6 eV.

19. A method for producing a semiconductor device, the method comprising:
arranging an intermediate layer on a chip carrier;
arranging a semiconductor chip on the intermediate layer; and
encapsulating the semiconductor chip with an encapsulation material,
wherein filler particles are embedded in at least one of the intermediate layer or the encapsulation material, which comprise a semiconductor material with a band gap in a range from 2.3 eV to 3.6 eV.

20. A method for producing a semiconductor device, the method comprising:
arranging an intermediate layer on a chip carrier;
arranging a semiconductor chip on the intermediate layer; and
encapsulating the semiconductor chip with an encapsulation material,
wherein filler particles are embedded in at least one of the intermediate layer or the encapsulation material, which are configured to increase at least one of an electrical conductivity of the intermediate layer or an electrical conductivity of the encapsulation material into a range from 10⁻¹⁶ S/m to 10⁻² S/m upon an increase in an electric field strength to a value of more than 5 V/μm.
